(19) United States
(12) Patent Application Publication
(10) Pub. No.: US 2025/0207565 A1
(43) Pub. Date: Jun. 26, 2025

(54) METHOD FOR DETERMINING TARGET POINTS OF HELIOSTATS DURING PREHEATING OF TOWER-TYPE SOLAR PHOTO-THERMAL POWER STATION

(71) Applicant: SEPCOIII ELECTRIC POWER CONSTRUCTION CO., LTD., Qingdao, Shandong (CN)

(72) Inventors: Zengli DAI, Qingdao, Shandong (CN); Renbao WANG, Qingdao, Shandong (CN); Tao LI, Qingdao, Shandong (CN); Xiupeng SONG, Qingdao, Shandong (CN); Zhaohui HAN, Qingdao, Shandong (CN); Dongxiang WANG, Qingdao, Shandong (CN); Yu JIANG, Qingdao, Shandong (CN); Yu XIE, Qingdao, Shandong (CN)

(21) Appl. No.: 18/851,124

(22) PCT Filed: Apr. 13, 2023
(86) PCT No.: PCT/CN2023/088109

§ 371 Date: Sep. 26, 2024

(30) Foreign Application Priority Data
Apr. 14, 2022 (CN) 202210389917.X

(51) Int. Cl. F03G 6/06; F03G 6/00; F24S 20/20; G06F 30/20

(52) U.S. Cl. CPC F03G 6/063; F03G 6/108; F24S 20/20; G06F 30/20

(57) ABSTRACT

A method for determining target points of heliostats during preheating of a tower-type solar photo-thermal power station comprises: establishing a coordinate system of a heliostat field of the station; obtaining coordinates of each heliostat according to a layout of the heliostat field; obtaining vertex coordinates of each heat absorbing panel on a heat absorber according to a layout of the heat absorbers; carrying out grid division for each panel to obtain vertex coordinates of each grid; obtaining X and Y coordinates of the target point of each heliostat on the panel; taking a Z coordinate of the target point of each heliostat on the panel as an independent variable and a sum of squares of differences between an actual number and an expected number of target points in each grid as an objective function to establish a non-linear optimization model, and solving the model to obtain the Z coordinate.

### TECHNICAL FIELD

The present invention pertains to the technical field of solar photo-thermal power generation, and specifically pertains to a method for determining target points of heliostats during preheating of a tower-type solar photo-thermal power station.

### BACKGROUND

With the commercialization of tower-type photo-thermal power generation, it has become a popular power generation method. As shown in FIG. 1, the principle of tower-type photo-thermal power generation is that a large amount of low-density energy from sun 4 is reflected onto heat absorbers 2 to become high-density solar energy by arranging tens of thousands of heliostats 1 around a heat absorption tower 3 in different geometric shapes, which is then converted into working medium thermal energy. From the point of view of the tower-type solar photo-thermal power stations that have been successfully implemented so far, the most popular one is the tower-type solar photo-thermal power station using molten salt as a working medium, which has the advantages of high power generation efficiency, stable output power and high-performance heat storage (it can generate electricity for up to 12 hours at night in commercial practice). Therefore, tower-type photo-thermal power generation using molten salt as a heat absorber is becoming increasingly popular.

However, for the tower-type photo-thermal power generation using the molten salt as an endothermic medium, it is necessary to preheat the heat absorber before the real power generation, and the power generation can be carried out only after the successful preheating, and failure to do so will bring the following consequences: decreased daily power generation time and decreased annual power generation, and shortened lifespan of the heat absorber due to non-uniform preheating. Thus, preheating becomes particularly important for the tower-type solar photo-thermal power stations that use the molten salt as the heat absorber. Usually, successful preheating mainly involves uniform heating and reaching a preset temperature of the heat absorbing panel after heating, with the most crucial aspect being uniform heating. The key to uniform heating is to appropriately distribute the target points of each heliostat well, the more uniform the target points, the more uniform the energy flux density on the heat absorbing panel. There is no research on the method of determining the target points of the heliostat during preheating.

### SUMMARY

In order to solve the above-mentioned technical problem, the present invention provides a method for determining target points of heliostats during preheating of a tower-type solar photo-thermal power station, which can achieve uniform energy flux density distribution on the heat absorbing panel, shorten preheating time, and improve power generation efficiency.

In order to achieve the above object, the present invention uses the following technical solutions.

A method for determining target points of heliostats during preheating of a tower-type solar photo-thermal power station, comprises the following steps:
step 1, establishing a coordinate system of a heliostat field of the tower-type solar photo-thermal power station;
step 2, obtaining coordinates of each heliostat according to a layout of the heliostat field of the tower-type solar photo-thermal power station;
step 3, obtaining vertex coordinates of each heat absorbing panel on a heat absorber according to a layout of the heat absorbers;
step 4, carrying out grid division for each heat absorbing panel of the heat absorber to obtain vertex coordinates of each grid;
step 5, obtaining an X coordinate and a Y coordinate of the target point of each heliostat on the heat absorbing panel according to the principle of minimum distance; and
step 6, according to the divided grids, taking a Z coordinate of the target point of each heliostat on the heat absorbing panel as an independent variable and a sum of squares of differences between an actual number of target points and an expected number of target points in each grid as an objective function to establish a non-linear optimization model, and solving the model to obtain the Z coordinate of the target point.

In the solution described above, in the step 1, an East-North-Up coordinate system is established with a center point of a ground where a heat absorption tower of the tower-type solar photo-thermal power station is located as an origin of coordinate.

In the solution described above, in the step 2, the coordinates of the heliostat refer to coordinates of a center point of a mirror of the heliostat, and coordinates of a ith heliostat are obtained according to a geometric layout of the heliostat field and expressed as (hxᵢ, hyᵢ, hzᵢ), i=1 . . . . W, where W is the number of heliostats in the heliostat field.

In the solution described above, in the step 3, the heat absorber is a regular n-gonal prism structure which comprises N heat absorbing panels, and each heat absorbing panel is rectangular; and coordinates of a jth vertex of a kth heat absorbing panel are obtained according to a height T of the heat absorption tower, a height H of the heat absorbing panel and a length L of a bottom edge of the heat absorbing panel and expressed as (Txₖⱼ, Tyₖⱼ, Tzₖⱼ), where k=1 . . . . N, and j=1, 2, 3 and 4.

In the solution described above, in the step 4, for the kth heat absorbing panel, a maximum value Xmaxₖ and a minimum value Xminₖ of an X axis and a maximum value Zmaxₖ and a minimum value Zminₖ of a Z axis are respectively obtained:

Xmaxₖ=max(Txₖ₁, . . . ,Txₖ₄)

Xminₖ=min(Txₖ₁, . . . ,Txₖ₄)

Zmaxₖ=max(Tzₖ₁, . . . ,Tzₖ₄)

Zminₖ=min(Tzₖ₁, . . . ,Tzₖ₄)
the kth heat absorbing panel is divided into M×F grids, and vertex coordinates of all grids in the X-axis direction are respectively

$$X {min}_{k} , X {min}_{k} + \frac{X {max}_{k} - X {min}_{k}}{M - 1} , … , X {max}_{k} ,$$

and the vertex coordinates of all grids in the Z-axis direction are respectively

$$Z {min}_{k} , Z {min}_{k} + \frac{Z {max}_{k} - Z {min}_{k}}{F - 1} , … , Z {max}_{k} .$$

In the solution described above, the step 5 specifically comprises the following steps: according to the principle of minimum distance, a horizontal distance from each heliostat to the target point is considered as a minimum distance from each heliostat to the heat absorption tower to obtain a circumcircle corresponding to a projection of the heat absorption tower on a horizontal plane:

$${x}^{2} + {y}^{2} = \frac{{L}^{2}}{4 \cdot {tan}^{2} ( \frac{π}{N} )}$$

where x and y are the X coordinate and the Y coordinate of the target point of the heliostat respectively;
for the ith heliostat (hxᵢ, hyᵢ, hzᵢ), a following equation is simultaneous:

$$\{ \begin{matrix}{x}^{2} + {y}^{2} = \frac{{L}^{2}}{4 \cdot {tan}^{2} ( \frac{π}{N} )} \\ y = \frac{{hy}_{i}}{{hx}_{i}} x\end{matrix}$$

and the X coordinate and the Y coordinate of the target point of the ith heliostat are obtained by solving,

$$x = \frac{{Lhx}_{i}}{2 \cdot tan ( \frac{π}{N} ) \sqrt{{hx}_{i}^{2} + {hy}_{i}^{2}}} \\ y = \frac{{Lhy}_{i}}{2 \cdot tan ( \frac{π}{N} ) \sqrt{{hx}_{i}^{2} + {hy}_{i}^{2}}} .$$

In the solution described above, in the step 6, the established non-linear optimization model is as follows:

$$min {‖ \vec{C} ( {z}_{1} , … , {z}_{W} ) - \vec{N} ‖}^{2}$$

$$s . t Z min \leq {z}_{i} \leq Zman$$

where [symbol] (z₁, . . . , z_{W})=(c₁, . . . , c_{N×M×F}) refers to the actual number of target points in each grid on the heat absorbing panel under a Z coordinate of a current corresponding target point of the heliostat; where z₁ refers to a Z coordinate of a corresponding target point of a first heliostat, z_{W} refers to a Z coordinate of a corresponding target point of a wth heliostat, c₁ refers to the actual number of target points in a first grid, C_{N×M×F} refers to the actual number of target points in a N×M×Fth grid, and a grid to which the Z coordinate of the target point belongs is determined according to the vertex coordinates of the grids obtained previously, and finally, the number of the target points corresponding to each grid is summarized; N×M×F refers to the total number of grids;

$$\vec{N} = ( {n}_{1} , … , {n}_{N \times M \times F} ) = ( \frac{W}{N \times M \times F} , … , \frac{W}{N \times M \times F} )$$

where n₁ refers to an expected number of target points in the first grid, N_{N×M×F} refers to an expected number of target points in a N×M×Fth grid, and is W a total number of heliostats;
zᵢ refers to a Z coordinate of the corresponding target point of the ith heliostat, Zmin is a minimum value of a Z coordinate of the heat absorbing panel, and Zmax is a maximum value of the Z coordinate of the heat absorbing panel; and
a MATLAB tool is used to solve an optimal solution of the non-linear optimization model, namely the Z coordinate of the target point of each heliostat.

With the technical solutions described above, the method for determining target points of heliostats during preheating of a tower-type solar photo-thermal power station according to the present invention has the following beneficial effects:
1. In the present invention, a non-linear optimization model is used to set preheating target points, and the heliostats are evenly distributed into each grid as the expected number of target points, thus achieving more scientific arrangement of the preheating target points, and resulting in more uniform energy flux density distribution, greatly shortened preheating time, and improved power generation efficiency.
2. In the present invention, a two-stage method (calculation of the X and Y coordinates is followed by calculation of the Z coordinate) is used to arrange the preheating target points, which further simplifies operation of the heliostats and greatly improves the preheating efficiency.

### BRIEF DESCRIPTION OF THE DRAWINGS

In order to illustrate the technical solutions of the embodiments of the present invention or the prior art more clearly, the accompanying drawings required for the description of the embodiments or the prior art will be briefly introduced below.

FIG. 1 is a schematic view of a heliostat field of a tower-type solar photo-thermal power station;

FIG. 2 is a flow chart of a method for determining target points of heliostats during preheating of a tower-type solar photo-thermal power station;

FIG. 3 is a structural schematic view of a heat absorber; and

FIG. 4 is a schematic diagram of a circumcircle corresponding to a projection of a heat absorption tower on a horizontal plane.

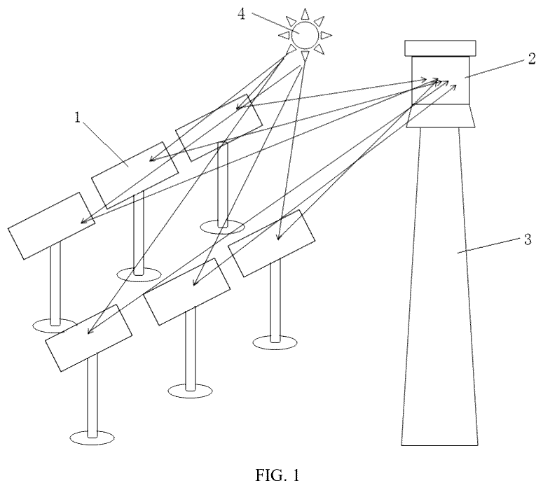

Reference numerals in the figures: 1. heliostat; 2. heat absorber; 3. heat absorption tower; 4. sun; 5. heat absorbing panel.

### DESCRIPTION OF THE EMBODIMENTS

The technical solutions of the embodiments of the present invention will be described clearly and completely below with reference to the accompanying drawings in the embodiments of the present invention.

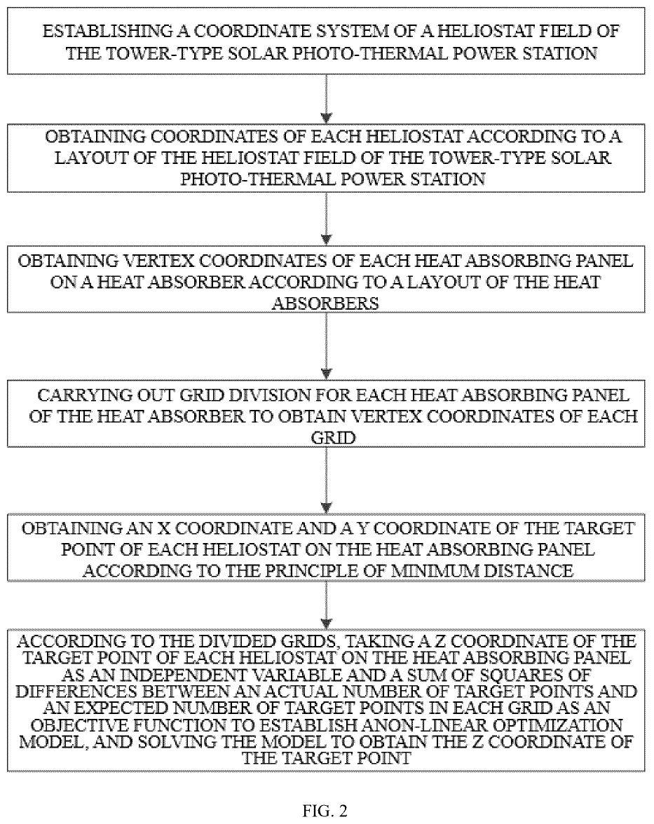

The present invention provides a method for determining target points of heliostats during preheating of a tower-type solar photo-thermal power station. As shown in FIG. 2, the method comprises the following steps:

Step 1, establishing a coordinate system of a heliostat field of the tower-type solar photo-thermal power station; at which an East-North-Up (ENU) coordinate system is established with a center point of a ground where a heat absorption tower 3 of the tower-type solar photo-thermal power station is located as an origin of coordinate.

Step 2, obtaining coordinates of each heliostat 1 according to a layout of the heliostat field of the tower-type solar photo-thermal power station; at which the coordinates of the heliostat 1 refer to coordinates of a center point of a mirror of the heliostat 1, and coordinates of a ith heliostat 1 are obtained according to a geometric layout of the heliostat field and expressed as (hxᵢ, hyᵢ, hzᵢ), i=1 . . . . W, where W is the number of heliostats 1 in the heliostat field.

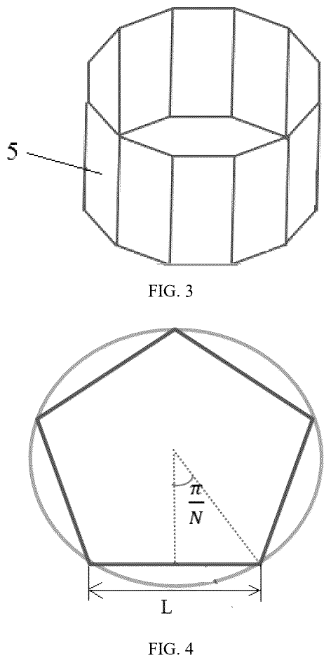

Step 3, obtaining vertex coordinates of each heat absorbing panel 5 on a heat absorber 2 according to a layout of the heat absorbers 2; as shown in FIG. 3, the heat absorber 2 is a regular n-gonal prism structure which comprises N heat absorbing panels 5, and each heat absorbing panel 5 is rectangular; and coordinates of a jth vertex of a kth heat absorbing panel 5 are obtained according to a height T of the heat absorption tower 3, a height H of the heat absorbing panel 5 and a length L of a bottom edge of the heat absorbing panel 5 and expressed as (Txₖⱼ, Tyₖⱼ, Tzₖⱼ), where k=1 . . . . N, and j=1, 2, 3 and 4.

Step 4, carrying out grid division for each heat absorbing panel 5 of the heat absorber 2 to obtain vertex coordinates of each grid;
for the kth heat absorbing panel, a maximum value Xmaxₖ and a minimum value Xminₖ of an X axis and a maximum value Zmaxₖ and a minimum value Zminₖ of a Z axis are respectively obtained:

Xmaxₖ=max(Txₖ₁, . . . ,Txₖ₄)

Xminₖ=min(Txₖ₁, . . . ,Txₖ₄)

Zmaxₖ=max(Tzₖ₁, . . . ,Tzₖ₄)

Zminₖ=min(Tzₖ₁, . . . ,Tzₖ₄)
the kth heat absorbing panel 5 is divided into M×F grids, and vertex coordinates of all grids in the X-axis direction are respectively

$$X {min}_{k} , X {min}_{k} + \frac{X {max}_{k} - X {min}_{k}}{M - 1} , … , X {max}_{k} ,$$

and the vertex coordinates of all grids in the Z-axis direction are respectively

$$Z {min}_{k} , Z {min}_{k} + \frac{Z {max}_{k} - Z {min}_{k}}{F - 1} , … , Z {max}_{k} .$$

Step 5, obtaining an X coordinate and a Y coordinate of the target point of each heliostat 1 on the heat absorbing panel 5 according to the principle of minimum distance; as shown in FIG. 4, according to the principle of minimum distance, a horizontal distance from each heliostat 1 to the target point is considered as a minimum distance from each heliostat 1 to the heat absorption tower 3 to obtain a circumcircle corresponding to a projection of the heat absorption tower 3 on a horizontal plane:

$${x}^{2} + {y}^{2} = \frac{{L}^{2}}{4 \cdot {tan}^{2} ( \frac{π}{N} )}$$

where x and y are the X coordinate and the Y coordinate of the target point of the heliostat 1 respectively;
for the ith heliostat 1 (hxᵢ, hyᵢ, hzᵢ), a following equation is simultaneous:

$$\{ \begin{matrix}{x}^{2} + {y}^{2} = \frac{{L}^{2}}{4 \cdot {tan}^{2} ( \frac{π}{N} )} \\ y = \frac{{hy}_{i}}{{hx}_{i}} x\end{matrix}$$

the X coordinate and the Y coordinate of the target point of the ith heliostat 1 are obtained by solving,

$$x = \frac{{Lhx}_{i}}{2 \cdot tan ( \frac{π}{N} ) \sqrt{{hx}_{i}^{2} + {hy}_{i}^{2}}} \\ y = \frac{{Lhy}_{i}}{2 \cdot tan ( \frac{π}{N} ) \sqrt{{hx}_{i}^{2} + {hy}_{i}^{2}}} \cdot Step$$

The established non-linear optimization model is as follows:

$$min {‖ \vec{C} ( {z}_{1} , … , {z}_{W} ) - \vec{N} ‖}^{2}$$

$$s . t Z min \leq {z}_{i} \leq Zman$$

where [symbol] (z₁, . . . , z_{W})=(c₁, . . . , c_{N×M×F}) refers to the actual number of target points in each grid on the heat absorbing panel 5 under a Z coordinate of a current corresponding target point of the heliostat 1; where z₁ refers to a Z coordinate of a corresponding target point of a first heliostat 1, z_{W} refers to a Z coordinate of a corresponding target point of a wth heliostat 1, c₁ refers to the actual number of target points in a first grid, C_{N×M×F} refers to the actual number of target points in a N×M×Fth grid, and a grid to which the Z coordinate of the target point belongs is determined according to the vertex coordinates of the grids obtained previously, and finally, the number of the target points corresponding to each grid is summarized; N×M×F refers to the total number of grids;

$$\vec{N} = ( {n}_{1} , … , {n}_{N \times M \times F} ) = ( \frac{W}{N \times M \times F} , … , \frac{W}{N \times M \times F} )$$

where n₁ refers to an expected number of target points in the first grid, n_{N×M×F} refers to an expected number of target points in a N×M×Fth grid, and is W a total number of heliostats 1;
zᵢ refers to a Z coordinate of the corresponding target point of the ith heliostat 1, Zmin is a minimum value of a Z coordinate of the heat absorbing panel 5, and Zmax is a maximum value of the Z coordinate of the heat absorbing panel 5; and
a MATLAB tool is used to solve an optimal solution of the non-linear optimization model, namely the Z coordinate of the target point of each heliostat 1.

The previous description of the disclosed embodiments is provided to enable any person skilled in the art to make or use the present invention. Various modifications to these embodiments will be readily apparent to those skilled in the art, and the generic principles defined herein may be implemented in other embodiments without departing from the spirit or scope of the present invention. Thus, the present invention is not intended to be limited to the embodiments shown herein but is to be accorded the widest scope consistent with the principles and novel features disclosed herein.

What is claimed is:

1. A method for determining target points of heliostats during preheating of a tower-type solar photo-thermal power station, comprising the following steps:
step 1, establishing a coordinate system of a heliostat field of the tower-type solar photo-thermal power station;
step 2, obtaining coordinates of each heliostat according to a layout of the heliostat field of the tower-type solar photo-thermal power station;
step 3, obtaining vertex coordinates of each heat absorbing panel on a heat absorber according to a layout of the heat absorbers;
step 4, carrying out grid division for each heat absorbing panel of the heat absorber to obtain vertex coordinates of each grid;
step 5, obtaining an X coordinate and a Y coordinate of the target point of each heliostat on the heat absorbing panel according to the principle of minimum distance; and
step 6, according to the divided grids, taking a Z coordinate of the target point of each heliostat on the heat absorbing panel as an independent variable and a sum of squares of differences between an actual number of target points and an expected number of target points in each grid as an objective function to establish a non-linear optimization model, and solving the model to obtain the Z coordinate of the target point.

2. The method for determining target points of heliostats during preheating of a tower-type solar photo-thermal power station according to claim 1, wherein in the step 1, an East-North-Up coordinate system is established with a center point of a ground where a heat absorption tower of the tower-type solar photo-thermal power station is located as an origin of coordinate.

3. The method for determining target points of heliostats during preheating of a tower-type solar photo-thermal power station according to claim 1, wherein in the step 2, the coordinates of the heliostat refer to coordinates of a center point of a mirror of the heliostat, and coordinates of a ith heliostat are obtained according to a geometric layout of the heliostat field and expressed as (hxᵢ, hyᵢ, hzᵢ), i=1 . . . . W, where W is the number of heliostats in the heliostat field.

4. The method for determining target points of heliostats during preheating of a tower-type solar photo-thermal power station according to claim 1, wherein in the step 3, the heat absorber is a regular n-gonal prism structure which comprises N heat absorbing panels, and each heat absorbing panel is rectangular; and coordinates of a jth vertex of a kth heat absorbing panel are obtained according to a height T of the heat absorption tower, a height H of the heat absorbing panel and a length L of a bottom edge of the heat absorbing panel and expressed as (Txₖⱼ, Tyₖⱼ, Tzₖⱼ), where k=1 . . . . N, and j=1, 2, 3 and 4.

5. The method for determining target points of heliostats during preheating of a tower-type solar photo-thermal power station according to claim 4, wherein in the step 4, for the kth heat absorbing panel, a maximum value Xmaxₖ and a minimum value Xminₖ of an X axis and a maximum value Zmaxₖ and a minimum value Zminₖ of a Z axis are respectively obtained:
Xmaxₖ=max(Txₖ₁, . . . ,Txₖ₄)
Xminₖ=min(Txₖ₁, . . . ,Txₖ₄)
Zmaxₖ=max(Tzₖ₁, . . . ,Tzₖ₄)
Zminₖ=min(Tzₖ₁, . . . ,Tzₖ₄)
the kth heat absorbing panel is divided into M×F grids, and vertex coordinates of all grids in the X-axis direction are respectively
$$X {min}_{k} , X {min}_{k} + \frac{X {max}_{k} - X {min}_{k}}{M - 1} , … , X {max}_{k} ,$$
and the vertex coordinates of all grids in the Z-axis direction are respectively
$$Z {min}_{k} , Z {min}_{k} + \frac{Z {max}_{k} - Z {min}_{k}}{F - 1} , … , Z {max}_{k} .$$

6. The method for determining target points of heliostats during preheating of a tower-type solar photo-thermal power station according to claim 4, wherein the step 5 specifically comprises the following steps: according to the principle of minimum distance, a horizontal distance from each heliostat to the target point is considered as a minimum distance from each heliostat to the heat absorption tower to obtain a circumcircle corresponding to a projection of the heat absorption tower on a horizontal plane:
$${x}^{2} + {y}^{2} = \frac{{L}^{2}}{4 \cdot {tan}^{2} ( \frac{π}{N} )}$$
where x and y are the X coordinate and the Y coordinate of the target point of the heliostat respectively;
for the ith heliostat (hxᵢ, hyᵢ, hzᵢ), a following equation is simultaneous:
$$\{ \begin{matrix}{x}^{2} + {y}^{2} = \frac{{L}^{2}}{4 \cdot {tan}^{2} ( \frac{π}{N} )} \\ y = \frac{{hy}_{i}}{{hx}_{i}} x\end{matrix}$$
and the X coordinate and the Y coordinate of the target point of the ith heliostat are obtained by solving,
$$x = \frac{{Lhx}_{i}}{2 \cdot tan ( \frac{π}{N} ) \sqrt{{hx}_{i}^{2} + {hy}_{i}^{2}}} \\ y = \frac{{Lhy}_{i}}{2 \cdot tan ( \frac{π}{N} ) \sqrt{{hx}_{i}^{2} + {hy}_{i}^{2}}} .$$

7. The method for determining target points of heliostats during preheating of a tower-type solar photo-thermal power station according to claim 5, wherein in the step 6, the established non-linear optimization model is as follows:
$$min {‖ \vec{C} ( {z}_{1} , … , {z}_{W} ) - \vec{N} ‖}^{2}$$
$$s . t Z min \leq {z}_{i} \leq Zman$$
where [symbol] (z₁, . . . , z_{W})=(c₁, . . . , c_{N×M×F}) refers to an actual number of target points in each grid on the heat absorbing panel under a Z coordinate of a current corresponding target point of the heliostat; where z₁ refers to a Z coordinate of a corresponding target point of a first heliostat, z_{W} refers to a Z coordinate of a corresponding target point of a wth heliostat, c₁ refers to an actual number of target points in a first grid, C_{N×M×F} refers to an actual number of target points in a N×M×Fth grid, and a grid to which the Z coordinate of the target point belongs is determined according to the vertex coordinates of the grids obtained previously, and finally, the number of the target points corresponding to each grid is summarized; N×M×F refers to a total number of grids;
$$\vec{N} = ( {n}_{1} , … , {n}_{N \times M \times F} ) = ( \frac{W}{N \times M \times F} , … , \frac{W}{N \times M \times F} )$$
where n₁ refers to an expected number of target points in the first grid, n_{N×M×F} refers to an expected number of target points in a N×M×Fth grid, and is W a total number of heliostats;
zᵢ refers to a Z coordinate of the corresponding target point of the ith heliostat, Zmin is a minimum value of a Z coordinate of the heat absorbing panel, and Zmax is a maximum value of the Z coordinate of the heat absorbing panel; and
a MATLAB tool is used to solve an optimal solution of the non-linear optimization model, namely the Z coordinate of the target point of each heliostat.
